(19) United States
(12) Patent Application Publication
(10) Pub. No.: US 2024/0224633 A1
(43) Pub. Date: Jul. 4, 2024

(54) DISPLAY DEVICE

(71) Applicant: LG Display Co., Ltd., Seoul (KR)

(72) Inventor: Yeonjun OH, Gimpo-si (KR)

(73) Assignee: LG Display Co., Ltd., Seoul (KR)

(21) Appl. No.: 18/391,159

(22) Filed: Dec. 20, 2023

(30) Foreign Application Priority Data
Dec. 30, 2022 (KR) 10-2022-0190616

(51) Int. Cl. H10K 59/127; H10K 59/126; H10K 59/38; H10K 59/80

(52) U.S. Cl. CPC H10K 59/127; H10K 59/126; H10K 59/38; H10K 59/873; H10K 59/8791

(57) ABSTRACT

According to an aspect of the present disclosure, a display device includes a first substrate having an active area including a plurality of sub-pixels and a non-active area surrounding the active area, a second substrate facing the first substrate, a dam attaching the first substrate and the second substrate in the non-active area, and a pad disposed outside the dam on one side of the first substrate. The second substrate includes a first part overlapping the active area, and a second part in contact with the first part, overlapping a portion of the non-active area between the active area and the pad, and made of a transparent conducting oxide or an oxide semiconductor. Therefore, reliability of the display device can be improved.

### CROSS-REFERENCE TO RELATED APPLICATIONS

This application claims priority to Korean Patent Application No. 10-2022-0190616 filed on Dec. 30, 2022, in the Republic of Korea, the entire contents of which are hereby expressly incorporated by reference into the present application.

### BACKGROUND

### Technical Field

The present disclosure relates to a display device, and more particularly, to a display device having improved reliability.

### Discussion of the Related Art

Display devices are used in computer monitors, TVs, mobile phones, and the like and include an organic light emitting display (OLED) that emits light by itself, a liquid crystal display (LCD) that requires a separate light source, and the like.

Such display devices are being applied to various fields including not only in the field of computer monitors and TVs, but in personal or other mobile devices such as video monitors, digital frame displays, signage displays, wearable devices, navigation devices, etc. As such, display devices having a reduced volume and weight while having a wide display area are being studied.

Further, flexible display device that can display images even when folded or rolled by forming a display element, lines, and the like on a flexible substrate made of a flexible material has received considerable attention as a next-generation display device.

However, some display devices can be more prone to external moisture and oxygen penetrating into the display device, which need to be addressed in order to improve reliability and performance of the display device. Further, a display device with a more simplified manufacturing process is desired to reduce manufacturing costs and time.

### SUMMARY OF THE DISCLOSURE

An object to be achieved by the present disclosure is to provide a display device in which damage to or a loss of a pad unit can be reduced or prevented.

Another object to be achieved by the present disclosure is to provide a display device in which a separate process for exposing a pad unit is omitted, thereby simplifying the process.

Objects of the present disclosure are not limited to the above-mentioned objects, and other objects, which are not mentioned above, can be clearly understood by those skilled in the art from the following descriptions.

A display device according to an aspect of the present disclosure includes a first substrate having an active area including a plurality of sub-pixels and a non-active area surrounding the active area; a second substrate facing the first substrate; a dam attaching the first substrate and the second substrate in the non-active area; and a pad disposed outside the dam on one side of the first substrate, wherein the second substrate includes: a first part overlapping the active area; and a second part in contact with the first part, overlapping a portion of the non-active area between the active area and the pad, and made of a transparent conducting oxide or an oxide semiconductor.

According to an aspect of the present disclosure, a display device includes a first substrate including an active area and a non-active area adjacent to the active area, the active area including a plurality of sub-pixels; a second substrate facing the first substrate and having a size smaller than a size of the first substrate; and a dam disposed in the non-active area between the first substrate and the second substrate, wherein the second substrate includes a first part disposed in the active area and the non-active area, and a second part disposed only in the non-active area, and ends of the second part and the dam are aligned with each other.

Other detailed matters of the exemplary embodiments are included in the detailed description and the drawings.

According to the present disclosure, a portion of an upper substrate corresponding to a pad unit is formed of a transparent conducting oxide or oxide semiconductor, so that a laser cutting process for exposing the pad unit can be omitted so as to simplify the manufacturing process.

According to the present disclosure, damage to or a loss of a lower substrate, inorganic layers, pads, and link lines corresponding to a pad unit can be prevented, and reliability of a display device can be improved.

The effects according to the present disclosure are not limited to the contents exemplified above, and more various effects are included in the present specification.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to an exemplary embodiment of the present disclosure.

FIG. 2 is a cross-sectional view cut along line II-II′ of FIG. 1.

FIG. 3 is a cross-sectional view cut along line III-III′ of FIG. 1.

FIGS. 4A to 4C are cross-sectional views illustrating a method of manufacturing the display device according to an exemplary embodiment of the present disclosure.

FIG. 5 is a plan view of a display device according to another exemplary embodiment of the present disclosure.

FIG. 6 is a cross-sectional view of a display device according to still another exemplary embodiment of the present disclosure.

### DETAILED DESCRIPTION OF THE EMBODIMENTS

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only”. Any references to singular can include plural unless expressly stated otherwise. Further, the term “exemplary” is interchangeably used with and has the same or similar meaning as the term “example.”

Components are interpreted to include an ordinary error range even if not expressly stated.

When the position relation between two parts (e.g., layers) is described using the terms such as “on,” “above,” “over,” “below,” “under,” and “next”, one or more additional parts (e.g., layers) can be positioned between the two parts unless the terms are used with the term “immediately” or “directly”.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, the embodiments of the present disclosure will be described in detail with reference to accompanying drawings. All the features of each display device according to all embodiments of the present disclosure are operatively coupled and configured.

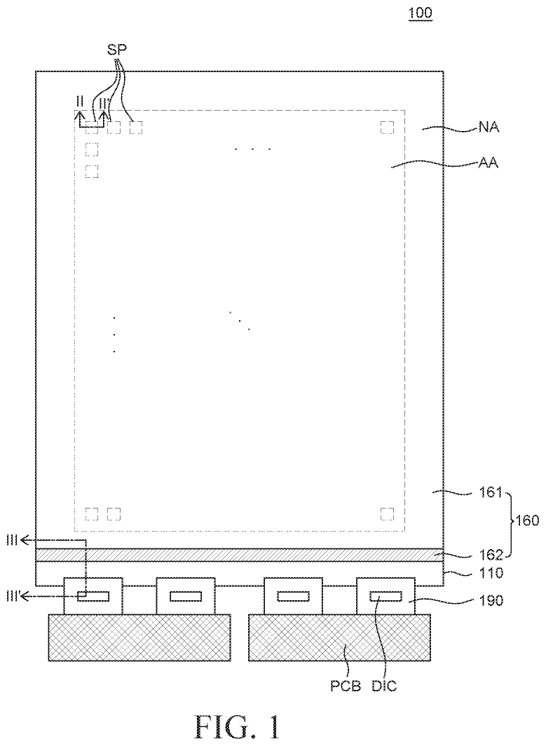

FIG. 1 is a plan view of a display device according to an exemplary embodiment of the present disclosure.

Referring to FIG. 1, a display device 100 according to an exemplary embodiment of the present disclosure includes a first substrate 110, a second substrate 160, flexible films 190, and a printed circuit boards PCB. The display device 100 includes various other components such as gate lines, data lines, etc. For brevity of description, these components are shown in FIG. 1 whereas some other components present in the display device 100 may not be shown.

The first substrate 110 is a substrate for supporting and protecting various components of the display device 100. The first substrate 110 includes an active area AA and a non-active area NA. The non-active area NA can surround the active area AA completely or in part. In this example, the non-active area NA completely surrounds the active area AA. The first substrate 110 can be formed of a plastic material having flexibility. For example, the first substrate 110 can be formed of polyimide (PI). However, the present disclosure is not limited thereto.

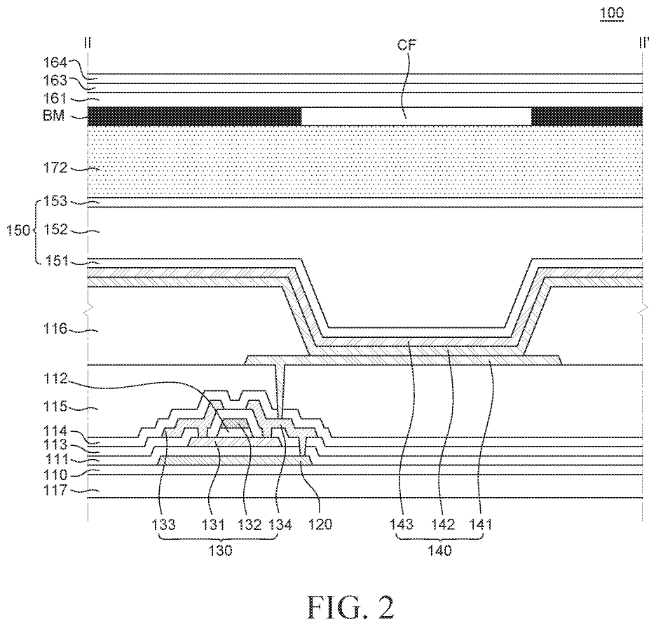

The active area AA can be disposed in a central portion of the first substrate 110 and can be an area where an image is displayed on the display device 100. Display elements and various driving elements for driving the display elements can be disposed in the active area AA. For example, each display element can be configured as a light emitting element 140 including an anode 141, a light emitting layer 142, and a cathode 143 to be described later referring to FIG. 2, but other types of display elements can be used. In addition, various driving elements/circuits such as a transistor 130 (FIG. 2), a capacitor, and lines for driving the display elements can be disposed in the active area AA.

A plurality of sub-pixels SP can be included in the active area AA. The sub-pixels SP are minimum units constituting a screen, and each of the plurality of sub-pixels SP can include the light emitting element 140 and a driving circuit. The plurality of sub-pixels SP can be defined at intersection areas of a plurality of gate lines disposed in a first direction and a plurality of data lines disposed in a second direction different from the first direction. However, the plurality of sub-pixels can be arranged in different configurations. Here, the first direction can be a horizontal direction of FIG. 1 and the second direction can be a vertical direction of FIG. 1, but the present disclosure is not limited thereto. Each of the plurality of sub-pixels SP can emit light of different wavelengths. For example, the plurality of sub-pixels SP can include a red sub-pixel, a green sub-pixel, and a blue sub-pixel. In other examples, the plurality of sub-pixels SP can further include a white sub-pixel. Different combinations of such color sub-pixels can be repeated arranged in the active area AA to display images.

The driving circuit of the sub-pixel SP is a circuit for controlling driving of the corresponding light emitting element 140 (FIG. 2). For example, the driving circuit can include a switching transistor, a driving transistor, a capacitor and the like. The driving circuit can be electrically connected to signal lines such as the gate lines, the data lines and the like that are connected to gate drivers, data drivers and the like disposed in the non-active area NA.

The non-active area NA is disposed in a circumferential area of the first substrate 110 and can be an area in which an image is not displayed. The non-active area NA can be disposed to surround the active area AA completely as shown in FIG. 1, but is not limited thereto. Various elements for driving the plurality of sub-pixels SP disposed in the active area AA can be disposed in the non-active area NA. For example, a driver integrated circuit (IC) supplying signals for driving the plurality of sub-pixels SP, the driving circuit, the signal lines, the flexible films 190, and the like can be disposed in the non-active area NA. In this case, the driver IC can include one or more of a gate driver, a data driver, and the like. In an example, the entire active area AA and the entire non-active area AA of a display panel can be disposed on the first substrate 110.

The second substrate 160 is disposed to face the first substrate 110 and cover the first substrate 110. The size of the second substrate 160 can be smaller than the size of the first substrate 110 in that the second substrate 160 as disposed covers only a part of the first substrate 110. For instance, the second substrate 160 covers a majority of the first substrate 110, but not the entire first substrate 110 (e.g., in an area connected to the flexible films 190 to be discussed later). The second substrate 160 can be an encapsulation substrate for protecting various components disposed on the first substrate 110. The second substrate 160 includes a first part 161 and a second part 162. The second substrate 160 can be attached to the first substrate 110 by a dam 171 to be described later and seal components of the display device 100.

The first part 161 can be a portion of the second substrate 160 that overlaps the active area AA (e.g., in the active area AA). The first part 161 can be disposed both in the active area AA and the non-active area NA. In an example, the first part 161 can cover the entire active area AA as well as portion of the non-active area NA. The first part 161 can be formed of a plastic material having flexibility. For example, the first part 161 can be formed of polyimide (PI). However, the present disclosure is not limited thereto.

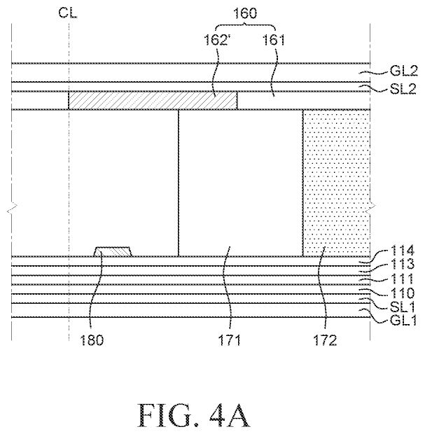

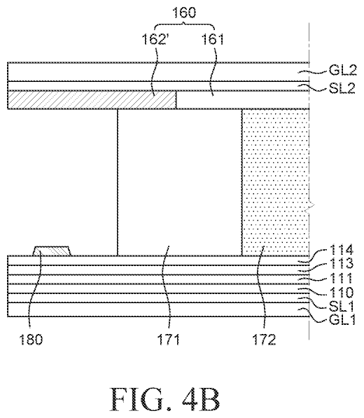

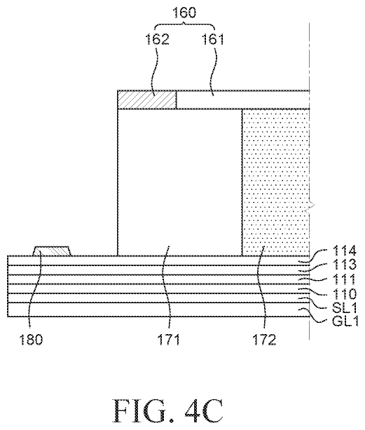

The second part 162 can be a part extending from the first part 161 and overlapping a portion of the non-active area NA (e.g., in the non-active area NA). In particular, the second part 162 can be disposed along an end portion of the first part 161 adjacent to the flexible films 190. In an example, the entire second part 162 is disposed in the non-active area NA and covers another portion of the non-active area NA. The second part 162 can be formed of a transparent conducting oxide or an oxide semiconductor. Accordingly, defects or limitations which can occur when a pad unit is exposed for attachment of the flexible films 190 can be eliminated or minimized. This will be described later with reference to FIGS. 4A to 4C.

The second part 162 can be formed of a transparent conducting oxide (TCO) such as indium tin oxide (ITO), indium zinc oxide (IZO), or indium zinc tin oxide (ITZO). In another example, the second part 162 can be formed of an oxide semiconductor material formed of indium (In) and gallium (Ga), for example, a transparent oxide semiconductor such as indium gallium zinc oxide (IGZO), indium gallium oxide (IGO) or indium tin zinc oxide (ITZO). However, types of materials of the transparent conducting oxide and the oxide semiconductor are exemplarily provided, and the second part 162 can be formed of other transparent conducting oxide and/or oxide semiconductor materials not described herein, and the present disclosure is not limited thereto.

The flexible films 190 are disposed in a portion of the non-active area NA of the first substrate 110 in which the second substrate 160 is not disposed. In this case, the flexible films 190 can be disposed on the pad unit of the first substrate 110. The pad unit is a part of the non-active area NA of the first substrate 110 and can refer to a part where a plurality of pads 180 to be described later are disposed. The flexible films 190 can be connected to the plurality of pads 180 to supply driving signals to the plurality of sub-pixels SP and the driving circuit in the active area AA. Specifically, one end portions of the flexible films 190 can be disposed in the non-active area NA to supply power voltages, data voltages, and the like to the plurality of sub-pixels and the driving circuit in the active area AA. Meanwhile, although FIG. 1 shows four flexible films 190, the number of the flexible films 190 can be variously changed according to design and is not limited thereto.

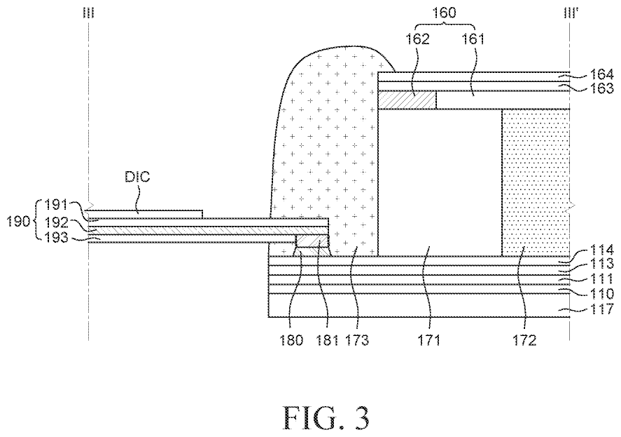

As mentioned above, an area of the first substrate 110 where the flexible films 190 are disposed does not overlap the second substrate 160. For example, the flexible film 190 can be disposed on an area of the first substrate 110 that is exposed without being covered by the second substrate 160 (FIG. 3). In other words, the second substrate 160 is not disposed on a portion of the non-active area NA where the flexible film 190 is disposed. Accordingly, the flexible film 190 can be easily connected to the first substrate 110 during a manufacturing process of the display device 100.

A driver IC DIC is mounted on the flexible film 190. Depending on a mounting method, the driver IC DIC can be disposed in a method such as a chip-on-glass (COG) method, a chip-on-film (COF) method, or a tape carrier package (TCP) method. However, for convenience of description, in the present disclosure, descriptions have been made assuming that the driver IC DIC is mounted on the flexible film 190 in the chip-on-film (COF) method, but the present disclosure is not limited thereto.

The driver IC DIC is a component that processes data signals for displaying images and various driving signals for processing them. The driver IC DIC can include a gate driver IC, a data driver IC, and the like. The driver IC DIC can supply driving signals to the first substrate 110 through a conductive layer 192 of the flexible film 190 (FIG. 3), so that the display device 100 can be driven.

The printed circuit boards PCB are connected to the plurality of flexible films 190. The printed circuit board PCB is a component that supplies signals to the driver IC DIC. Various components for supplying various signals such as driving signals and data signals to the driver IC DIC can be disposed on the printed circuit board PCB. Meanwhile, in FIG. 1, it is illustrated that two printed circuit boards PCB are provided and one printed circuit board PCB is connected to two flexible films 190, but the number of the printed circuit boards PCB and a connection structure thereof can be variously changed according to design, and the present disclosure is not limited thereto.

In an example, an additional printed circuit board connected to the printed circuit board PCB can be further disposed. For example, the printed circuit board PCB can be referred to as a source printed circuit board (Source PCB; S-PCB) on which a data driver is mounted, and the additional printed circuit board connected to the printed circuit board PCB can be referred to as a control printed circuit board (Control PCB; C-PCB) on which a timing controller or the like is mounted. Other variations are possible.

FIG. 2 is a cross-sectional view cut along line II-II′ of FIG. 1, which will now be described in more detail. Particularly, FIG. 2 shows a cross-sectional view of a sub-pixel area in the active area AA on the display panel of the display device 100 according to an example of the present disclosure.

Referring to FIG. 2, the display device 100 includes the first substrate 110, a light blocking layer 120, the transistor 130, the light emitting element 140, an encapsulation part 150, a barrier film 117, the second substrate 160, color filters CF, a black matrix BM, a polarizing plate 163, a cover film 164, and a filling member 172. The display device 100 can be implemented as a top emission type display device, but is not limited thereto.

The barrier film 117 is disposed under the first substrate 110. The barrier film 117 can be disposed to protect the first substrate 110 that is flexible. When the first substrate 110 is formed of a plastic material such as polyimide, a separate component can be needed to protect the first substrate 110 due to flexible properties of the first substrate 110.

The barrier film 117 can protect the display device 100 from external impacts, moisture, or heat. The barrier film 117 can be formed of a polymer resin having lightness and unbreakable properties. For example, the barrier film 117 can be formed of a cyclo-olefin polymer (COP), but is not limited thereto, and can be formed of materials such as polyimide (PI), polycarbonate (PC), and polyethylene terephthalate (PET).

The light blocking layer 120 is disposed on the first substrate 110. The light blocking layer 120 can be disposed to overlap with the transistor 130. The light blocking layer 120 can be formed of a metallic material and electrically connected to a source electrode 133 or a drain electrode 134 of the transistor 130. For example, the light blocking layer 120 can be formed of a conductive material such as copper (Cu), aluminum (Al), molybdenum (Mo), nickel (Ni), titanium (Ti), chromium (Cr), or an alloy thereof, but the present disclosure is not limited thereto. Further, the light blocking layer 120 can be electrically connected to the drain electrode 134, but is not limited thereto. The light blocking layer 120 can be selectively formed only in a necessary area. For example, the light blocking layer 120 can be disposed to overlap with the transistor 130 functioning as a driving transistor, but is not limited thereto. For example, the light blocking layer 120 can also be disposed below transistors other than the driving transistor.

The light blocking layer 120 can block potential generation on a surface of the first substrate 110 and light introduced from the outside. In particular, the light blocking layer 120 can overlap with an active layer 131 of the transistor 130. Accordingly, the light blocking layer 120 can prevent a channel region of the active layer 131 from being deteriorated. In addition, the light blocking layer 120 can protect the transistor 130 from charged particles that are generated from the first substrate 110 and minimize an effect on electric charges flowing through a channel of the transistor 130. Accordingly, a shift phenomenon and a current drop phenomenon of a threshold voltage of the transistor 130 can be reduced or minimized, and reliability of the display device 100 can be improved well.

Since the light blocking layer 120 is formed of a metallic material, the light blocking layer 120 and the active layer 131 are also components that form a capacitance. In this case, if the light blocking layer 120 is electrically floating, variations in parasitic capacitance can occur, and a shift amount of the threshold voltage of the transistor 130 can be varied. This can cause visual defects such as luminance changes. Accordingly, by electrically connecting the light blocking layer 120 with the drain electrode 134 as an example, the parasitic capacitance can be maintained constantly and the visual defect issue can be effectively addressed. For example, the same voltage as that of the drain electrode 134 can be applied to the light blocking layer 120. However, the present disclosure is not limited thereto, and the light blocking layer 120 can be electrically connected to the source electrode 133 so that the same voltage as the source electrode 133 can be applied to the light blocking layer 120.

A buffer layer 111 is disposed on the first substrate 110 and the light blocking layer 120. The buffer layer 111 can reduce penetration of moisture or impurities through the first substrate 110. In addition, the buffer layer 111 can protect the transistor 130 from impurities such as alkali ions flowing out from the first substrate 110. In addition, the buffer layer 111 can improve an adhesive strength between layers formed thereon and the first substrate 110. The buffer layer 111 can be composed of a single layer or multiple layers of silicon oxide (SiOx) or silicon nitride (SiNx), but is not limited thereto. The buffer layer 111 can be an optional component and can be omitted based on a type and material of the first substrate 110, a structure and type of the transistor 130, and the like. Meanwhile, the buffer layer can also be disposed between the first substrate 110 and the light blocking layer 120 in some cases.

The transistor 130 is disposed on the buffer layer 111. The transistor 130 can be used as the driving element for driving the light emitting element 140 in the active area AA. The transistor 130 includes the active layer 131, a gate electrode 132, the source electrode 133 and the drain electrode 134. The transistor 130 illustrated in FIG. 2 is a driving transistor and is a thin film transistor having a top gate structure in which the gate electrode 132 is disposed on the active layer 131. However, the present disclosure is not limited thereto, and the transistor 130 can be implemented as a transistor with a bottom gate structure.

Although the driving transistor 130 among various transistors included in the display device 100 is illustrated in FIG. 2, other transistors such as switching transistors can also be disposed.

The active layer 131 is disposed on the buffer layer 111. The active layer 131 is an area where a channel is formed when the transistor 130 is driven. The active layer 131 can be formed of an oxide semiconductor, amorphous silicon (a-Si), polycrystalline silicon (poly-Si), or an organic semiconductor.

A gate insulating layer 112 is disposed on the active layer 131. The gate insulating layer 112 is a layer for electrically insulating the active layer 131 and the gate electrode 132 and can be formed of an insulating material. As illustrated in FIG. 2, the gate insulating layer 112 can be patterned to have the same width (or similar width) as the gate electrode 132 on the active layer 131 or can be formed over an entire surface of the first substrate 110, but the present disclosure is not limited thereto. The gate insulating layer 112 can be formed of a single layer or multiple layers of silicon oxide (SiOx) or silicon nitride (SiNx), but is not limited thereto.

The gate electrode 132 is disposed on the gate insulating layer 112. The gate electrode 132 is disposed on the gate insulating layer 112 to overlap the channel region of the active layer 131. The gate electrode 132 can be formed of any one of various metallic materials, for example, molybdenum (Mo), aluminum (Al), chromium (Cr), gold (Au), titanium (Ti), nickel (Ni), neodymium (Nd), and copper (Cu), an alloy of two or more of them, or a multilayer thereof, but the present disclosure is not limited thereto.

An interlayer insulating layer 113 is disposed on the gate electrode 132. The interlayer insulating layer 113 can be formed of a single layer or multiple layers of silicon oxide (SiOx) or silicon nitride (SiNx), but is not limited thereto. Contact holes through which the source electrode 133 and the drain electrode 134 come into contact with a source region and a drain region of the active layer 131, respectively, are formed in the interlayer insulating layer 113.

The source electrode 133 and the drain electrode 134 are disposed on the interlayer insulating layer 113. The source electrode 133 and the drain electrode 134 are disposed on the same layer to be spaced apart from each other. The source electrode 133 and the drain electrode 134 are electrically connected to the active layer 131 through the contact holes of the interlayer insulating layer. The source electrode 133 and the drain electrode 134 can be formed of any one of various metallic materials, for example, molybdenum (Mo), aluminum (Al), chromium (Cr), gold (Au), titanium (Ti), nickel (Ni), neodymium (Nd), and copper (Cu), an alloy of two or more of them, or a multilayer thereof, but the present disclosure is not limited thereto.

A passivation layer 114 is disposed on the transistor 130. The passivation layer 114 can be disposed to cover the source electrode 133, the drain electrode 134 and the interlayer insulating layer 113. The passivation layer 114 can be composed of a single layer or multiple layers of silicon oxide (SiOx) or silicon nitride (SiNx), but is not limited thereto.

A planarization layer 115 is disposed on the passivation layer 114. The planarization layer 115 is an insulating layer for protecting the transistor 130 and planarizing an upper portion of the transistor 130. A contact hole for exposing the drain electrode 134 of the transistor 130 is formed in the planarization layer 115. However, the present disclosure is not limited thereto, and a contact hole for exposing the source electrode 133 can be formed in the planarization layer 115. The planarization layer 115 can be formed of one of acrylic resin, epoxy resin, phenolic resin, polyamide resin, polyimide resin, unsaturated polyester resin, polyphenylene resin, polyphenylene sulfide resin, benzocyclobutene, and photoresist, but the present disclosure is not limited thereto.

The light emitting element 140 is disposed on the planarization layer 115. The light emitting element 140 includes the anode 141, the light emitting layer 142 and the cathode 143.

The anode 141 is disposed on the planarization layer 115. The anode 141 is disposed to correspond to each of the plurality of sub-pixels SP. The anode 141 can be electrically connected to the drain electrode 134 of the transistor 130 through the contact hole. However, the anode 141 can be electrically connected to the source electrode 133 of the transistor 130 depending on a type of the transistor 130 and a design method of the driving circuit.

The anode 141 can be formed of a conductive material having a high work function in order to supply holes to the light emitting layer 142. The anode 141 can have a multilayer structure including a transparent conductive layer and an opaque conductive layer having high reflective efficiency. The transparent conductive layer can be formed of a material having a relatively high work function value, such as indium tin oxide (ITO) or indium zinc oxide (IZO). The opaque conductive layer can have a single-layer or multilayer structure including Al, Ag, Cu, Pb, Mo, Ti, or an alloy thereof. However, a material of the anode 141 is not limited thereto.

A bank 116 is disposed on the planarization layer 115 and the anode 141. The bank 116 can be formed on the planarization layer 115 to cover an edge of the anode 141. The bank 116 is an insulating layer disposed between the plurality of sub-pixels SP to distinguish the plurality of sub-pixels SP. The bank 116 can be formed of an organic insulating material. For example, the bank 116 can be formed of one of acrylic resin, epoxy resin, phenolic resin, polyamide resin, polyimide resin, unsaturated polyester resin, polyphenylene resin, polyphenylene sulfide resin, benzocyclobutene, and photoresist, but is not limited thereto.

The light emitting layer 142 is disposed on the anode 141 and the bank 116. The light emitting layer 142 can be an organic layer for emitting white light. The light emitting layer 142 can further include various layers such as a hole transport layer, a hole injection layer, a hole blocking layer, an electron injection layer, an electron blocking layer, and an electron transport layer.

The cathode 143 is disposed on the light emitting layer 142. The cathode 143 can be formed as a single layer over the entire surface of the first substrate 110. For example, the cathode 143 can be a common layer commonly formed in the plurality of sub-pixels SP. Since the cathode 143 supplies electrons to the light emitting layer 142, it can be formed of a conductive material having a low work function. For example, the cathode 143 can be formed of a transparent conductive material such as indium tin oxide (ITO) or indium zinc oxide (IZO), a metal alloy such as MgAg, or an ytterbium (Yb) alloy. The cathode 143 can further include a metal doping layer, but the present disclosure is not limited thereto.

The encapsulation part 150 is disposed on the light emitting element 140. For example, the encapsulation part 150 is disposed on the cathode 143 to cover the light emitting element 140. The encapsulation part 150 protects the light emitting element 140 from external moisture and oxygen penetrating into the display device 100. The encapsulation part 150 can have a structure in which an inorganic layer and an organic layer are alternately stacked. In this example, the encapsulation part 150 includes a first encapsulation layer 151, a foreign material cover layer 152, and a second encapsulation layer 153, but other variations are possible.

The first encapsulation layer 151 can be disposed on the cathode 143 to suppress penetration of moisture or oxygen. The first encapsulation layer 151 can be formed of an inorganic material such as silicon nitride (SiNx), silicon oxynitride (SiNxOy), silicon oxide (SiOx), or aluminum oxide (AlyOz), but the present disclosure is not limited thereto.

The foreign material cover layer 152 is disposed on the first encapsulation layer 151 to planarize a surface thereof. In addition, the foreign material cover layer 152 can cover foreign materials or particles that can occur in a manufacturing process. The foreign material cover layer 152 can be formed of an organic material, such as silicon oxycarbon (SiOxCz), acrylic or epoxy-based resin, but the present disclosure is not limited thereto.

The second encapsulation layer 153 is disposed on the foreign material cover layer 152 and can suppress penetration of moisture or oxygen, similar to the first encapsulation layer 151. The second encapsulation layer 153 can be formed of an inorganic material such as silicon nitride (SiNx), silicon oxynitride (SiNxOy), silicon oxide (SiOx), or aluminum oxide (AlyOz), but is not limited thereto. The second encapsulation layer 153 can be formed of the same material as the first encapsulation layer 151 or can be formed of a material different therefrom.

Meanwhile, the color filter CF is disposed under the first part 161 of the second substrate 160. In particular, the color filter CF is disposed on a surface of the second substrate 160 facing the first substrate 110. The color filter CF is disposed to correspond to the light emitting element 140. For example, the color filter CF can be disposed in emission areas in which the anode 141 and the light emitting layer 142 directly contact each other in the plurality of sub-pixels SP. The emission area can refer to an area in which light is substantially emitted within the sub-pixel SP. The color filter CF can convert light emitted from the light emitting element 140 into light of a specific color. For example, the color filters CF can include a red color filter, a green color filter, and a blue color filter. Accordingly, white light emitted from the light emitting element 140 can pass through the color filter CF and be converted into red, green, or blue light.

The black matrix BM is disposed on the surface of the second substrate 160 facing the first substrate 110. The black matrix BM can be disposed in an area where the color filter CF is not disposed. For example, the black matrix BM can be disposed in an area excluding the emission areas in the plurality of sub-pixels SP. The black matrix BM can distinguish the plurality of sub-pixels SP. The black matrix BM can reduce color mixing between the plurality of sub-pixels SP adjacent to each other. Further, the black matrix BM can prevent components such as the driving circuit from being visually recognized.

The polarizing plate 163 is disposed on the second substrate 160, e.g., on the first part 161. In particular, the polarizing plate 163 can be disposed on an outer surface of the second substrate 160 facing outwardly, not on the surface of the second substrate 160 facing the first substrate 110. The polarizing plate 163 can selectively transmit light and reduce reflection of external light incident onto the display device 100. Specifically, the display device 100 contains various metallic materials that are applied to semiconductor elements, lines, light emitting elements, and the like. Accordingly, external light incident onto the display device 100 can be reflected by the metallic material, and visibility of the display device 100 can be reduced due to the reflection of the external light. In this case, by disposing the polarizing plate 163 to prevent reflection of external light on the outer surface of the second substrate 160, visibility of the display device 100 can be improved.

The cover film 164 is disposed on the polarizing plate 163. The cover film 164 can be a component that is exposed to the outside of the display device 100 and protect the display device 100 from external impacts and scratches. In addition, the cover film 164 can protect the display device 100 from moisture or the like introduced from the outside.

The filling member 172 is disposed to fill a space between components of the first substrate 110 and components of the second substrate 160. Specifically, the filling member 172 can be disposed between the encapsulation part 150 on the first substrate 110 and the black matrix BM and the color filter CF on the second substrate 160. In addition, the filling member 172 can be disposed to fill an inner space of the dam 171 (FIG. 3) to be described later. The filling member 172 can serve to attach the first substrate 110 and the second substrate 160. In addition, the filling member 172 can seal the display device 100 well and protect the light emitting elements 140 from external moisture, oxygen, impacts, and the like. The filling member 172 can be formed of a material that can be cured by both ultraviolet rays and heat. For example, the filling member 172 can be formed of any one of acrylic, epoxy, silicone, and rubber resin or a mixture thereof, but the present disclosure is not limited thereto.

Now, FIG. 3 will be described in more detail. FIG. 3 is a cross-sectional view cut along line III-III′ of FIG. 1 and illustrates a cross-sectional view of the non-active area NA of the display panel as well as the flexible film 190.

Referring to FIG. 3, the display device 100 includes the first substrate 110, the pad 180, the barrier film 117, the flexible film 190, the second substrate 160, the polarizing plate 163, the cover film 164, the dam 171, the filling member 172 and a sealing member 173.

The pad 180 is disposed in the non-active area NA on one side of the first substrate 110 and is disposed outside and separate from the side of the first substrate 110. Further, the pad 180 can be disposed outside and separate from the dam 171. The pad 180 can be disposed on the passivation layer 114, but is not limited thereto. In addition, the pad 180 can be formed of any one of various metallic materials, for example, molybdenum (Mo), aluminum (Al), chromium (Cr), gold (Au), titanium (Ti), nickel (Ni), neodymium (Nd), and copper (Cu), an alloy of two or more of them, or a multilayer thereof, but the present disclosure is not limited thereto. Further, the pad 180 can be a transparent conducting oxide such as indium tin oxide (ITO) or indium zinc oxide (IZO), but the present disclosure is not limited thereto.

The plurality of pads 180 can be provided on one side of the first substrate 110 and connected to the flexible films 190. The pads 180 can be connected to the plurality of sub-pixels of the active area AA through link lines extending from the active area AA to the non-active area NA. Accordingly, signals that are applied from the flexible films 190 can be transmitted to the plurality of sub-pixels through the pads 180 and the link lines.

The flexible film 190 includes a base layer 191, the conductive layer 192 and a protective layer 193.

The base layer 191 can be a flexible insulating film supporting components of the flexible film 190. The base layer 191 can include, for example, polycarbonate, polyethylene terephthalate, polyimide, polyamide, polyester, polyacrylate, polymethyl methacrylate, and the like, but the present disclosure is not limited thereto.

The conductive layer 192 is disposed on or under the base layer 191. The conductive layer 192 can be provided in plural so that a plurality of conductive layers 192 can be provided. A portion of the plurality of conductive layers 192 can electrically connect the driver IC DIC and the pad 180. For example, a portion of the plurality of conductive layers 192 can transfer signals from the driver IC DIC to the plurality of sub-pixels SP. Another portion of the plurality of conductive layers 192 can electrically connect the driver IC DIC and the printed circuit board PCB. For example, another portion of the plurality of conductive layers 192 can transmit signals from the printed circuit board PCB to the driver IC DIC. The conductive layers 192 can be formed of a metallic material including copper (Cu), silver (Ag), gold (Au), or aluminum (Al), but is not limited thereto.

The protective layer 193 is disposed on or under the base layer 191 to cover the conductive layer 192. The protective layer 193 can protect components of the flexible film 190. For example, the protective layer 193 can protect components of the flexible film 190 from external impacts. Further, when manufacturing the display device 100, a temporary substrate can be disposed under the first substrate 110 to perform a process, and can be separated after the process is completed. The temporary substrate can be removed by a laser lift off (LLO) process, and the protective layer 193 can prevent an inside of the flexible film 190 from being damaged by laser light during the LLO process.

The protective layer 193 may not be formed at the end portion of the flexible film 190. For example, the protective layer 193 has an area smaller than the base layer 191 and exposes a portion of the conductive layer 192. The conductive layer 192 that is exposed by the protective layer 193 can be electrically connected to the pad 180.

A conductive adhesive layer 181 is disposed between the pad 180 and the conductive layer 192. The conductive adhesive layer 181 can electrically connect the pad 180 and the conductive layer 192. The conductive adhesive layer 181 is an adhesive member containing conductive particles and can be formed of, for example, an anisotropic conductive film (ACF). The anisotropic conductive film (ACF) is a resin component film having conductive balls that are used for adhesion and electrical conduction. In the anisotropic conductive film, the conductive balls, which are conductive particles, are dispersed in a resin layer to conduct current, and the anisotropic conductive film can maintain an adhesive strength by being cured by heat and pressure. However, the first adhesive layer 181 of the present disclosure is not limited to such materials.

The conductive balls of the conductive adhesive layer 181 can be formed of metals such as gold (Au), silver (Ag), tin (Tin), nickel (Ni), chromium (Cr), iron (Fe), cobalt (Co), platinum (Pt), and copper (Cu) and alloys thereof. Alternatively, the conductive ball can be formed to have a core including glass, ceramic, or polymer resin, a metal formed on a surface of the core, and an alloy thereof, but the present disclosure is not limited thereto.

The resin layer of the conductive adhesive layer 181 can be a curable organic polymer that has adhesiveness and is cured by heat or light. Specifically, the resin layer can be formed of a thermal-curing resin, and can include epoxy resin, phenolic resin, urea resin, melamine resin, unsaturated polyester resin, resorcinol resin, and the like, but the present disclosure is not limited thereto.

Bonding of the first substrate 110 and the flexible film 190 can be performed, for example, by a tap bonding process. Specifically, when pressure is applied in a state where the conductive adhesive layer 181 is disposed between the first substrate 110 and the flexible film 190, the pad 180 and the conductive layer 192 can be electrically connected by the conductive balls dispersed in the resin layer.

The dam 171 is configured to attach the first substrate 110 and the second substrate 160 together. The dam 171 can be disposed along circumferences of the first substrate 110 and the second substrate 160. In particular, in an area adjacent to the pad 180, an end portion of the dam 171 and an end portion of the second part 162 can be disposed on the same plane. For example, the ends of the dam 171 and ends of the second part 162 may be aligned or substantially aligned. The dam 171 can block moisture or oxygen penetrating into a side surface of the display device 100. The filling member 172 can fill a space between the first substrate 110 and the second substrate 160 that are attached by the dam 171.

Meanwhile, an adhesive strength of the dam 171 can be higher than an adhesive strength of the filling member 172. Accordingly, an outside portion of the second part 162 can be easily removed together with the temporary substrate supporting the second substrate 160, when manufacturing the display device 100. This will be described later with reference to FIGS. 4A to 4C.

The sealing member 173 can be disposed on the first substrate 110 to surround a side portion of the display device 100. For example, the sealing member 173 can be disposed on the passivation layer 114 outside the dam 171 to surround an upper portion of the first substrate 110, a side surface of the dam 171, a side surface of the second substrate 160, a side surface of the polarizing plate 163, and a side surface of the cover film 164. Further, the sealing member 173 can seal the pad 180 and the flexible film 190 that are connected to each other at the outside of the dam 171. Accordingly, the sealing member 173 can prevent penetration of moisture or oxygen into a connection area between the pad 180 and the flexible film 190. Further, the sealing member 173 can minimize moisture permeation into the side surface of the display device 100.

The sealing member 173 can be formed of a non-conductive material having elasticity to seal the side surface of the display device 100 and at the same time, to supplement rigidity of the side surface of the display device 100. Also, the sealing member 173 can be formed of an adhesive material. In addition, the sealing member 173 can further include a moisture absorbent to absorb moisture and oxygen from the outside to minimize moisture permeation through the side portion of the display device 100. For example, the sealing member 173 can be formed of polyimide (PI), polyurethane, epoxy, or acrylic-based materials, but is not limited thereto.

The first part 161 of the second substrate 160 extends from an area overlapping (in) the active area AA to an area overlapping the dam 171. The second part 162 of the second substrate 160 can be disposed to overlap a portion of the non-active area NA between the active area AA and the pad 180. The second part 162 is disposed along and extends directly from the end portion of the first part 161 adjacent to the pad 180. For example, the second part 162 can extend from a side surface of the first part 161 adjacent to the pad 180. In particular, the second part 162 can be disposed to completely overlap with the dam 171, e.g., the entire second part 162 can be disposed on the top surface of the dam 171. Accordingly, the end portion of the second part 162 and the end portion of the dam 171 can be disposed on the same plane (e.g., can be aligned with each other).

The first part 161 and the second part 162 are disposed to contact each other. In this case, a boundary between the first part 161 and the second part 162 can overlap the dam 171. For example, one portion of the dam 171 can overlap the first part 161 and another portion of the dam 171 can overlap the second part 162. Accordingly, when the temporary substrate supporting the second substrate 160 is removed, the first part 161 and the second part 162 can be fixed to and by the dam 171 without being separated along with the temporary substrate.

Hereinafter, a method of manufacturing the display device 100 according to an embodiment of the present disclosure will be described in detail with reference to FIGS. 4A to 4C.

Particularly, FIGS. 4A to 4C are cross-sectional views illustrating a method of manufacturing a display device according to an exemplary embodiment of the present disclosure, and focus on the features of FIG. 3.

First, referring to FIG. 4A, a first sacrificial layer SL1 and a first temporary substrate GL1 are disposed under the first substrate 110. Since the first substrate 110 has flexible properties, the first temporary substrate GL1 can support the first substrate 110 during the manufacturing process of the display device 100. In a state where the first temporary substrate GL1 is disposed below the first substrate 110, the light blocking layer 120, the transistor 130, the light emitting element 140, the encapsulation part 150, and the pad 180 described above are disposed on the first substrate 110.

A second sacrificial layer SL2 and a second temporary substrate GL2 are disposed on one surface of the second substrate 160. Since the second substrate 160 has flexible properties, the second temporary substrate GL2 can support the second substrate 160 during the manufacturing process of the display device 100. In a state where the second temporary substrate GL2 is disposed below the second substrate 160, the color filter CF and the black matrix BM described above are formed on the second substrate 160. Meanwhile, the second substrate 160 includes the first part 161 and a pattern part 162′. The pattern part 162′ can become the second part 162 after the second sacrificial layer SL2 and the second temporary substrate GL2 are removed.

The first temporary substrate GL1 and the second temporary substrate GL2 can be formed of a rigid material. For example, the first temporary substrate GL1 and the second temporary substrate GL2 can be formed of glass, but are not limited thereto.

The first sacrificial layer SL1 is a layer formed to easily separate the first temporary substrate GL1 and the first substrate 110. The second sacrificial layer SL2 is a layer formed to easily separate the second temporary substrate GL2 and the second substrate 160. The first and second sacrificial layers SL1 and SL2 can be formed of amorphous silicon that is hydrogenated or amorphous silicon that is hydrogenated and doped with impurities.

Then, after the first substrate 110 and the second substrate 160 are positioned to face each other, the first substrate 110 and the second substrate 160 are attached through the dam 171 and the filling member 172. In this case, the dam 171 can be formed to overlap a boundary between the first part 161 and the pattern part 162′ of the second substrate 160. An area of the first part 161 and an area of the pattern part 162′ that are in contact with the dam 171 can be similar to each other, but the present disclosure is not limited thereto. In addition, an area of the pattern part 162′ that does not overlap the dam 171 can protrude from the dam 171 and overlap the pad 180. The pattern part 162′ can further protrude from an area overlapping the pad 180 in a direction away from the dam 171.

A cutting line CL means a cutting line for separating the first substrate 110, components on the first substrate 110, the second substrate 160, and components on the second substrate 160 into a final display device 100. The cutting line CL can be located outside the pad 180. The cutting line CL can be located on the same line as an end portion of the pattern part 162′ that does not overlap the dam 171, but the present disclosure is not limited thereto.

Referring to FIG. 4B, a cutting process can be performed along the cutting line CL. Specifically, the first substrate 110, the buffer layer 111, the interlayer insulating layer 113, the passivation layer 114, the second substrate 160, and the like are subjected to laser cutting along the cutting line CL and are cut along the cutting line. Further, wheel scribing of the first sacrificial layer SL1, the first temporary substrate GL1, the second sacrificial layer SL2, and the second temporary substrate GL2 is performed by a cutting wheel. Since the first sacrificial layer SL1, the first temporary substrate GL1, the second sacrificial layer SL2, and the second temporary substrate GL2 can be formed of a material having rigidity higher than those of the display devices 100 such as the first substrate 110 and the second substrate 160, a scribing operation thereof can be performed by a cutting wheel instead of laser cutting. As such, the structure shown in FIG. 4B is obtained.

Referring to FIG. 4C, the second temporary substrate GL2 and the second sacrificial layer SL2 supporting the second substrate 160 are removed by a laser lift off (LLO) process. Specifically, when a laser is irradiated toward the second sacrificial layer SL2 from an upper portion of the second temporary substrate GL2, the second sacrificial layer SL2 can be dehydrogenated. Accordingly, the second sacrificial layer SL2 and the second temporary substrate GL2 can be separated from the second substrate 160.

During the LLO process of the second temporary substrate GL2 and the second sacrificial layer SL2, a portion of the pattern part 162′ protruding from the dam 171 can be removed together therewith. For example, a portion of the pattern part 162′ that does not contact the dam 171 can be removed along with the second temporary substrate GL2 and the second sacrificial layer SL2 during the LLO process. Accordingly, only the second part 162 finally exists on the dam 171.

Specifically, the pattern part 162′ or the second part 162 is formed of a transparent conducting oxide or an oxide semiconductor. For example, in the manufacturing process of the display device 100, the pattern part 162′ can be formed on the second sacrificial layer SL2 through a deposition process such as sputtering or the like. After forming of the dam 171, the pattern part 162′ in contact with the dam 171 can be strongly attached to the dam 171. On the other hand, the pattern part 162′ that is not in contact with the dam 171 can be connected only to the second sacrificial layer SL2. Accordingly, during the LLO process, the pattern part 162′ in contact with the dam 171 can remain while being attached to the dam 171 even if the second sacrificial layer SL2 is removed. On the other hand, the pattern part 162′ that is not in contact with the dam 171 can be removed together with the second sacrificial layer SL2. Thus, the second part 162 completely overlaps the dam 171 and can remain on the dam 171. Further, the end portion of the second part 162 can be located on the same plane as the end portion of the dam 171.

Meanwhile, an adhesive strength of the dam 171 can be higher than that of the filling member 172. In this case, a portion of the first part 161 can also be disposed to come into contact with the dam 171. For example, the first part 161 can also be strongly attached to the dam 171. Therefore, during the LLO process, the first part 161 can remain while being attached to the dam 171 without being removed along with the second sacrificial layer SL2 and the second temporary substrate GL2.

Thereafter, the flexible film 190 is connected to the pad 180, and the polarizing plate 163 and the cover film 164 are attached to an upper portion of the second substrate 160. In addition, the upper portion of the first substrate 110, the connection area between the pad 180 and the flexible film 190, the side surface of the dam 171, the side surface of the second substrate 160, the side surface of the polarizing plate 163, and the side surface of the cover film 164 can be sealed by the sealing member 173. In addition, by separating the first sacrificial layer SL1 and the first temporary substrate GL1 through the LLO process and attaching the barrier film 117 to a lower surface of the first substrate 110, the manufacturing process of the display device 100 can be completed.

In the manufacturing process of the display device, after laser cutting of an upper substrate and a lower substrate, a half-cut process of cutting the upper substrate overlapping the pad unit is performed. The half-cut process is performed by laser cutting only half of the upper substrate without cutting an entirety of the upper substrate in order to prevent damage to pads of the lower substrate and an area adjacent thereto. After the half-cut process, a wheel scribing process of an upper temporary substrate and a lower temporary substrate is performed. Thereafter, the upper temporary substrate is separated through the LLO process. In addition, the pad can be exposed by removing the upper substrate that has been half-cut through physical force.

However, even if laser irradiation is performed in a half-cut method, which is a method of laser cutting only about half of the upper substrate in order to minimize a laser reaching the lower substrate, the laser can reach the lower substrate. In this case, the pads and link lines can be damaged and cracks can occur, resulting in driving failure. In addition, when the lower substrate is irradiated with a laser, the lower substrate can be cut, which can create a possibility that the pad unit can be lost. In addition, if inorganic layers on the lower substrate are damaged, moisture permeation can occur, resulting in a decrease in reliability.

To address these issues, in the display device 100 according to an exemplary embodiment of the present disclosure, the second substrate 160 can include the first part 161 and the second part 162. The first part 161 can be a part extending from the active area AA to a portion of the dam 171. The second part 162 can be a part that is disposed between the first part 161 and the pad 180 and completely overlaps the dam 171. Further, the second part 162 can be formed of a transparent conducting oxide or an oxide semiconductor. Here, the second part 162 can be a part remaining after the pattern part 162′ overlapping the pad 180 has been removed by the LLO process.

Specifically, during the manufacturing process of the display device 100, the pattern part 162′ of the second substrate 160 can be disposed at a portion overlapping the pad 180 of the first substrate 110. In this case, one portion of the pattern part 162′ is attached to the dam 171, and a remaining portion of the pattern part 162′ overlapping the pad 180 protrudes from the dam 171. Accordingly, during the LLO process, the remaining portion of the pattern part 162′ that is not attached to the dam 171 can be separated along with the second sacrificial layer SL2 and the second temporary substrate GL2. For example, since the portion of the pattern part 162′ overlapping the pad 180 is removed by the LLO process, a separate half-cut process for exposing the pad 180 is unnecessary. Accordingly, the process of the display device 100 can be further simplified.

In particular, since a half-cut process of the second substrate 160 is omitted, damage to the pad unit can be prevented. For example, there is no need to irradiate a laser onto an area of the second substrate 160 corresponding to a boundary between the pad 180 and the dam 171 so as to expose the pad 180. Accordingly, damage to the pad 180 or the link line connected to the pad 180 due to laser irradiation can be prevented. In addition, damage to the first substrate 110 or insulating layers on the first substrate 110 due to laser irradiation can be prevented. Therefore, it is possible to prevent driving failure and moisture permeation of the display device 100 so as to to improve reliability of the display device 100.

In the display device 100 according to an exemplary embodiment of the present disclosure, the pattern part 162′ or the second part 162 can be formed of a transparent conducting oxide or an oxide semiconductor. In this case, the transparent conducting oxide and the oxide semiconductor can be materials allowing for an LLO process with the second sacrificial layer SL2 and the second temporary substrate GL2. Therefore, even if a partial area of the second substrate 160 is formed of a transparent conducting oxide or an oxide semiconductor, the LLO process can be easily performed. For example, even if the second substrate 160 is configured to include the first part 161 and the second part 162 that are formed of different materials from each other, the display device 100 can be easily manufactured using existing processes and equipment.

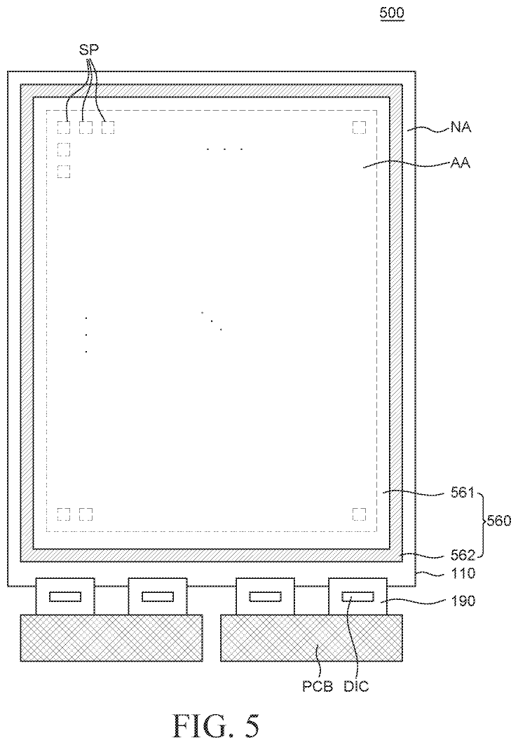

FIG. 5 is a plan view of a display device according to another exemplary embodiment of the present disclosure. Other configurations of a display device 500 of FIG. 5 are identical to (or similar to) those of the display device 100 of FIG. 1 to FIG. 4C with a difference in a second substrate 560, and thus duplicate descriptions thereof will be omitted or may be briefly provided.

Referring to FIG. 5, the second substrate 560 includes a first part 561 and a second part 562.

The first part 561 can be a portion of the second substrate 560 overlapping the active area AA. The first part 561 can extend from an area corresponding to the active area AA to an area corresponding to the non-active area NA. Further, an outer portion of the first part 561 can overlap the dam 171. The first part 561 can be formed of a plastic material having flexibility. For example, the first part 561 can be formed of polyimide (PI). However, the present disclosure is not limited thereto.

The second part 562 can be disposed to contact the first part 561 and to surround an entirety of the first part 561. The second part 562 can be disposed to completely overlap the dam 171. For example, an end portion of the second part 562 and an end portion of the dam 171 can be disposed on the same plane (e.g., aligned with each other). In particular, the end portion of the second part 562 can be disposed inside the end portion of the first substrate 110, overall. The second part 562 can be formed of a transparent conducting oxide or an oxide semiconductor.

In general, a laser can be irradiated onto a very narrow area, whereas a wheel scribing process is a mechanical scribing process. Thus, a width of an area that is cut by laser cutting is smaller than a width of an area that is cut by wheel scribing. Therefore, even if laser cutting and wheel scribing are performed on the same cutting line, an end portion of an upper temporary substrate and an end portion of an upper substrate may not be disposed on the same plane. For example, since a cut-width of the upper substrate is smaller than a cut-width of the upper temporary substrate, the end portion of the upper substrate can protrude more than the end portion of the upper temporary substrate. In this case, the protruding upper substrate can be bent, which can cause wrinkles. Even if the upper substrate is cut together with the upper temporary substrate during wheel scribing, a burr can be caused on the upper substrate, resulting in wrinkles. This can degrade exterior quality of the display device.

To address these issues, in the display device 500 according to another exemplary embodiment of the present disclosure, the second substrate 560 can include the first part 561 and the second part 562 surrounding an entirety of the first part 561. In this case, the end portion of the second part 562 can be disposed on the same plane as (e.g., aligned with) the end portion of the dam 171. Also, the end portion of the second part 562 can be disposed inside the end portion of the first substrate 110. The second part 562 can be formed of a transparent conducting oxide or an oxide semiconductor. Here, the second part 562 can be a part remaining after a pattern part formed of a transparent conducting oxide or an oxide semiconductor has been removed by an LLO process. Accordingly, it is possible to prevent wrinkles from occurring at an end portion of the second substrate 560 of the display device 500.

Specifically, after a laser cutting process of the first substrate 110 and the second substrate 560, a wheel scribing process of the first temporary substrate GL1, the first sacrificial layer SL1, the second temporary substrate GL2, and the second sacrificial layer SL2 can be performed. In addition, an LLO process of the second temporary substrate GL2 and the second sacrificial layer SL2 can be performed. In this case, one portion of the pattern part formed of the transparent conducting oxide or oxide semiconductor is attached to the dam 171, and the remaining portion of the pattern part protrudes from the dam 171. Accordingly, during the LLO process, areas of the pattern part protruding from the dam 171 can be separated along with the second sacrificial layer SL2 and the second temporary substrate GL2. Therefore, wrinkles are not created but even if wrinkles occur at an end portion of the pattern part by the laser cutting process and the wheel scribing process, the end portion of the pattern part can be removed by the LLO process. That is, since the end portion of the second part 562 is formed by the LLO process, occurrence of wrinkles or burrs can be minimized and addressed effectively. Accordingly, exterior quality of the display device 500 can be improved.

Since the second substrate 560 of the display device 500 includes the first part 561 and the second part 562, a separate half-cut process for exposing the pad 180 can be omitted. Accordingly, a process for the display device 500 can be further simplified. In addition, by omitting the half-cut process, damage to the first substrate 110, and insulating layers, the pad 180, and the link line on the first substrate 110 can be prevented. Therefore, it is possible to prevent driving failure and moisture permeation of the display device 500 and to improve reliability of the display device 500.

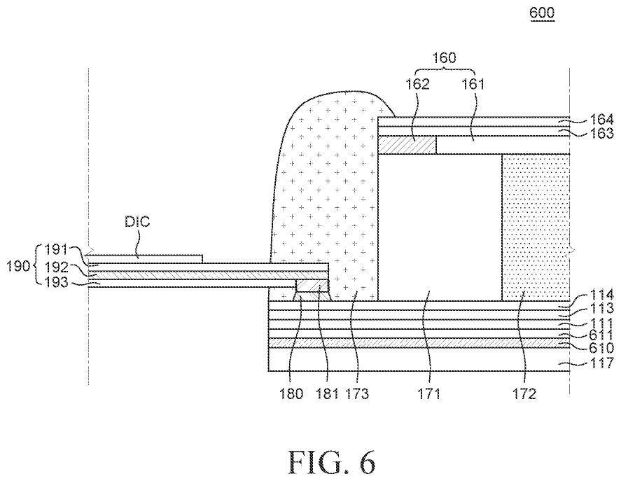

FIG. 6 is a cross-sectional view of a display device according to still another exemplary embodiment of the present disclosure. Other configurations of a display device 600 of FIG. 6 are identical to (or similar to) those of the display device 100 of FIG. 1 to FIG. 4C with a difference in a first substrate 610. Thus, duplicate descriptions thereof will be omitted or may be provided briefly.

Referring to FIG. 6, the first substrate 610 (similar to the first substrate discussed above) is a substrate for supporting and protecting various components of the display device 600. The first substrate 610 can be formed of any one of a transparent conducting oxide and an oxide semiconductor. For example, the first substrate 610 can be formed of a transparent conducting oxide (TCO) such as indium tin oxide (ITO), indium zinc oxide (IZO), or indium zinc tin oxide (ITZO). In addition, the first substrate 610 can be an oxide semiconductor material formed of indium (In) and gallium (Ga), for example, a transparent oxide semiconductor such as indium gallium zinc oxide (IGZO), indium gallium oxide (IGO) or indium tin zinc oxide (ITZO). However, types of materials of the transparent conducting oxide and the oxide semiconductor are exemplarily provided, and the first substrate 610 can be formed of other transparent conducting oxides and oxide semiconductor materials not described herein, but the present disclosure is not limited thereto.

The first substrate 610 can be formed by depositing a transparent conducting oxide or an oxide semiconductor at a very small thickness. Accordingly, since the first substrate 610 is formed to have a very small thickness, it can have flexibility. In the case of the display device 600 including the first substrate 610 having flexibility, it can be implemented as a flexible display device 600 capable of displaying images even when folded or rolled. For example, when the display device 600 is a foldable display device, the first substrate 610 can be folded or unfolded around a folding axis. For another example, when the display device 600 is a rollable display device, the display device can be rolled around a roller and stored. Therefore, the display device 600 according to still another exemplary embodiment of the present disclosure can be implemented as the flexible display device 600 such as a foldable display device or a rollable display device by using the first substrate 610 having flexibility.

In addition, in the case of the display device 600 according to still another exemplary embodiment of the present disclosure, the LLO process can be performed using the first substrate 610 formed of a transparent conducting oxide or an oxide semiconductor. For example, in a manufacturing process of the display device 600, a temporary substrate under the first substrate 610 and the first substrate 610 can be separated using a laser. Accordingly, in light of that that the first substrate 610 is a layer for an easier LLO process, it can be referred to as a functional thin film, a functional thin film layer, or a functional substrate.

A lower buffer layer 611 can be disposed on the first substrate 610 (between the first substrate 610 and the buffer layer 111. In another example, the buffer layer 111 so that the lower buffer layer 611 is present between the first substrate 610 and the interlayer insulating layer 113. The lower buffer layer 611 can prevent diffusion of moisture and/or oxygen penetrating from the outside of the first substrate 610. Moisture permeability of the display device 600 can be controlled by controlling a thickness or a stacked structure of the lower buffer layer 611. In addition, the lower buffer layer 611 can prevent a short circuit defect from occurring when the first substrate 610 formed of a transparent conducting oxide or an oxide semiconductor contacts the light blocking layer 120 or various lines. The lower buffer layer 611 can be formed of an inorganic material, and can be composed of, for example, a single layer or a double layer of silicon oxide (SiOx) or silicon nitride (SiNx), but the present disclosure is not limited thereto.

In the display device 600 according to still another exemplary embodiment of the present disclosure, a thickness of the display device 600 can be reduced by forming the first substrate 610 with any one of a transparent conducting oxide and an oxide semiconductor. In existing cases, plastic substrates were mainly used as substrates for display devices. However, since the plastic substrates are formed by coating and curing substrate materials at high temperature, there are limitations in that it takes a long time to form the plastic substrate and it is difficult to form the substrate thin to a certain level or less. On the other hand, a transparent conducting oxide and an oxide semiconductor can be formed to have a very small thickness through a deposition process such as sputtering. Accordingly, in the display device 600 according to still another exemplary embodiment of the present disclosure, the first substrate 610 supporting various components of the display device 600 is formed of a transparent conducting oxide layer or an oxide semiconductor layer, so that the thickness of the display device 600 can be reduced and a slim design thereof can be implemented.

In addition, in the display device 600 according to still another exemplary embodiment of the present disclosure, the first substrate 610 is formed of a transparent conducting oxide or an oxide semiconductor, so that flexibility of the display device 600 can be improved, and stress generated during deformation of the display device 600 can be reduced. Specifically, when the first substrate 610 is formed of a transparent conducting oxide layer or an oxide semiconductor, the first substrate 610 can be formed as a very thin film. In this case, the first substrate 610 can also be referred to as a first transparent thin film layer. Accordingly, the display device 600 including the first substrate 610 can have high flexibility, and the display device 600 can be easily bent or rolled. Therefore, in the display device 600 according to still another exemplary embodiment of the present disclosure, by forming the first substrate 610 with any one of a transparent conducting oxide layer and an oxide semiconductor layer, flexibility of the display device 600 is improved and stress generated when the display device 600 is deformed can also be alleviated, so that occurrence of cracks or the like in the display device 600 can be minimized.

In addition, in the display device 600 according to still another exemplary embodiment of the present disclosure, by forming the first substrate 610 with any one of a transparent conducting oxide layer and an oxide semiconductor layer, so that it is possible to reduce a possibility that static electricity is generated in the first substrate 610. If the first substrate is formed of plastics and static electricity is generated therein, various lines and driving elements on the first substrate can be damaged or a driving operation can be affected by the static electricity, thereby causing degradation in display quality.

Instead, when the first substrate 610 is formed of a transparent conducting oxide layer or an oxide semiconductor layer, generation of static electricity on the first substrate 610 can be prevented or minimized, and a configuration for blocking and discharging the static electricity can be simplified. Therefore, in the display device 600 according to still another exemplary embodiment of the present disclosure, by forming the first substrate 610 with either a transparent conducting oxide layer or an oxide semiconductor layer having a low possibility of generating static electricity, damage or degradation in display quality due to the static electricity can be minimized or eliminated.

In addition, in the display device 600 according to still another exemplary embodiment of the present disclosure, by forming the first substrate 610 with one of a transparent conducting oxide and an oxide semiconductor, it is possible to minimize penetration of external moisture or oxygen into the display device 600 through the first substrate 610. When the first substrate 610 is formed of a transparent conducting oxide layer or an oxide semiconductor, since the first substrate 610 is formed in a vacuum environment, a possibility of generating foreign materials is remarkably low. In addition, even if a foreign material is generated, since a size of the foreign material is very small, penetration of moisture and oxygen into the inside of the display device 600 can be minimized. Therefore, in the display device 600 according to still another exemplary embodiment of the present disclosure, by forming the first substrate 610 with a transparent conducting oxide or oxide semiconductor having a low possibility of generating foreign materials and excellent moisture permeability, it is possible to improve reliability of the light emitting element (OLED) including an organic layer and the display device 600 can be improved.

In addition, in the display device 600 according to still another exemplary embodiment of the present disclosure, the first substrate 610 is formed of either a transparent conducting oxide or an oxide semiconductor, and the barrier film 117 which is thin and inexpensive can be attached to a lower portion of the first substrate 610 and used. When the first substrate is formed of a material having low moisture permeability, such as plastics or the like, the moisture permeability can be supplemented by attaching a thick and expensive barrier film having high performance thereto.

However, in the display device 600 according to still another exemplary embodiment of the present disclosure, since the first substrate 610 is formed of a transparent conducting oxide or oxide semiconductor having excellent moisture permeability, it is possible to attach the barrier film 117 which is thin and inexpensive to the lower portion of the first substrate 610. Therefore, in the display device 600 according to still another exemplary embodiment of the present disclosure, by forming the first substrate 610 with either a transparent conducting oxide or oxide semiconductor having excellent moisture permeability, a manufacturing cost of the display device can be reduced.

In addition, in the display device 600 according to still another exemplary embodiment of the present disclosure, a laser lift off (LLO) process can be performed by forming the first substrate 610 with either a transparent conducting oxide or an oxide semiconductor. When the display device 600 is manufactured, the first temporary substrate GL1 on which the first sacrificial layer SL1 is formed is attached under the first substrate 610, and then, the transistor 130, the light emitting element 140 or the like can be formed on the first substrate 610. In this case, since the transparent conducting oxide and the oxide semiconductor are materials allowing for an LLO process with the first sacrificial layer SL1 and the first temporary substrate GL1. Thus, even if the first substrate 610 is formed of either a transparent conducting oxide or an oxide semiconductor, the first substrate 610 and the first temporary substrate GL1 can be easily separated. Therefore, in the display device 600 according to still another exemplary embodiment of the present disclosure, since the first substrate 610 is formed of either a transparent conducting oxide layer or an oxide semiconductor allowing for the LLO process, the display device 600 can be easily manufactured during an existing process and existing equipment.

In the display device 600 according to still another exemplary embodiment of the present disclosure, since the second substrate 160 includes the first part 161 and the second part 162, a separate half-cut process for exposing the pad 180 can be omitted. Accordingly, the process of the display device 600 can be further simplified. In addition, by omission of the half-cut process, damage to the first substrate 610, and insulating layers, the pad 180, and link lines on the first substrate 610 can be prevented. Therefore, it is possible to prevent driving failure and moisture permeation of the display device 600 and to improve reliability of the display device 600.

The exemplary embodiments of the present disclosure can also be described as follows:

According to an aspect of the present disclosure, a display device includes a first substrate having an active area including a plurality of sub-pixels and a non-active area surrounding the active area; a second substrate facing the first substrate; a dam attaching the first substrate and the second substrate in the non-active area; and a pad disposed outside the dam on one side of the first substrate. The second substrate includes: a first part overlapping the active area; and a second part in contact with the first part, overlapping a portion of the non-active area between the active area and the pad, and made of a transparent conducting oxide or an oxide semiconductor.

A boundary between the first part and the second part can overlap the dam. The first part can extend from an area overlapping the active area to an area overlapping the dam. The second part can be disposed to completely overlap the dam. An end portion of the second part can be disposed on the same plane as an end portion of the dam.

The second part can be disposed along an end portion of the first part adjacent to the pad. The second part can be disposed to surround an entirety of the first part.

An end portion of the second part can be disposed inside an end portion of the first substrate on sides other than the one side of the first substrate on which the pad is disposed. The first substrate can be made of a transparent conducting oxide or an oxide semiconductor.

The display device can further include a plurality of light emitting elements disposed to correspond to each of the plurality of sub-pixels; an encapsulation part covering the plurality of light emitting elements; and a filling member filling a space between the first substrate and the second substrate on the encapsulation part.

An adhesive strength of the dam can be higher than an adhesive strength of the filling member.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a first substrate including an active area and a non-active area adjacent to the active area, the active area including a plurality of sub-pixels;
a second substrate facing the first substrate;
a dam attaching the first substrate and the second substrate in the non-active area; and
a pad disposed outside the dam on one side of the first substrate,
wherein the second substrate includes:
a first part disposed across the active area and in the non-active area; and
a second part in contact with the first part, overlapping with a portion of the non-active area between the active area and the pad, and made of a transparent conducting oxide or an oxide semiconductor.

2. The display device of claim 1, wherein a boundary between the first part and the second part overlaps the dam.

3. The display device of claim 1, wherein the first part of the second substrate extends from an area overlapping the active area to an area overlapping the dam in the non-active area.

4. The display device of claim 1, wherein the second part of the second substrate is disposed to completely overlap with the dam.

5. The display device of claim 1, wherein an end portion of the second part is disposed to be aligned with an end portion of the dam.

6. The display device of claim 1, wherein the second part is disposed along one side of the first part.

7. The display device of claim 1, wherein the second part is disposed to surround an entirety of the first part.

8. The display device of claim 1, wherein an end portion of the second part is disposed inside from an end portion of the first substrate on sides other than the one side of the first substrate on which the pad is disposed.

9. The display device of claim 1, wherein the first substrate is made of a transparent conducting oxide or an oxide semiconductor.

10. The display device of claim 1, further comprising:
a plurality of light emitting elements disposed to correspond to the plurality of sub-pixels;
an encapsulation part covering the plurality of light emitting elements; and
a filling member disposed on the encapsulation part and filling a space between the first substrate and the second substrate.

11. The display device of claim 10, wherein an adhesive strength of the dam is higher than an adhesive strength of the filling member.

12. The display device of claim 10, further comprising:
a color filter and a black matrix disposed between the filling member and the first part of the second substrate;
a polarizing plate disposed on the color filter and the black matrix; and
a barrier film disposed under the first substrate.

13. A display device, comprising:
a first substrate including an active area and a non-active area adjacent to the active area, the active area including a plurality of sub-pixels;
a second substrate facing the first substrate and having a size smaller than a size of the first substrate; and
a dam disposed in the non-active area between the first substrate and the second substrate,
wherein the second substrate includes:
a first part disposed in the active area and the non-active area; and
a second part disposed only in the non-active area, and
wherein ends of the second part and the dam are aligned with each other.

14. The display device of claim 13, further comprising:
a pad disposed on an end portion of the first substrate, the end portion having no second substrate disposed thereabove; and
a sealing member covering the pad as well as the ends of the second part and the dam.

15. The display device of claim 13, wherein the first substrate is made of a transparent conducting oxide or an oxide semiconductor.

16. The display device of claim 13, wherein the second part is made of a transparent conducting oxide or an oxide semiconductor.
